(19) United States
(12) Patent Application Publication
(10) Pub. No.: US 2007/0194820 A1
(43) Pub. Date: Aug. 23, 2007

(54) Phase delay detection apparatus and method with multi-cycle phase range of operation

(75) Inventor: Abhishek Duggal, Bethlehem, PA (US)

Correspondence Address: LAW OFFICE OF JOHN LIGON, 213 E. HIGHLAND AVENUE, P.O. BOX 281, ATLANTIC HIGHLANDS, NJ, 07716, US

(73) Assignee: Agere Systems Inc

(21) Appl. No.: 11/358,260

(22) Filed: Feb. 21, 2006

(51) Int. Cl. H03L 7/06

(52) U.S. Cl. 327/158

(57) ABSTRACT

A method and apparatus is provided to assure that a delay line control loop will only lock at a desired phase difference—e.g., 360 degrees (and not at the desired phase difference plus a multiple of 360 degrees), between its input and output signals. The phase delay detector of the invention samples multiple signals, from internal stages of the delay line, which are then logically combined to assure that the VCDL will only lock at the desired phase difference.

### FIELD OF THE INVENTION

The invention relates generally to electronic circuits and particularly to timing and clock/data recovery circuits.

### BACKGROUND OF THE INVENTION

Delay lines are used in electronics equipment to provide an output with a known time or phase difference to the input signal. Of particular interest is a controlled delay line where the phase difference or the time delay can be varied via a fed-back control signal, usually a voltage level. This type of circuit is known as a voltage controlled delay line (VCDL).

A VCDL is often used to assure that its output represents a specific delay, typically represented as a phase difference, from an input, or clock signal. An exemplary implementation of such a VCDL is shown in FIG. 1.

In the illustrated implementation, the input clock signal is delayed by the VCDL. The amount of delay is controlled by the control signal. Both the input clock and the delayed version from the VCDL output are fed to a delay detector. The delay detector produces a signal that is a function of the phase difference between its two inputs. After suitable filtering to smooth out the digital waveform, the delay detector output operates as a control signal to effect any needed adjustment to the VCDL delay.

When this delay loop is locked in a stable state, the control signal is substantially constant, corresponding to a desired VCDL delay. Typically, the delay-locked loop is implemented as a “calibration” loop where the desired constant VCDL delay is 2π radians of phase—i.e., 360 degrees or 1 clock cycle.

A prior-art implementation of the phase-delay detector produces a constant voltage control signal (after suitable filtering) when the phase-delay between the input clock signal and the VCDL output is maintained at a predetermined level—illustratively 360 degrees. If the delay is less than 360 degrees, an incremental change is made in the control signal voltage, which is operated on by the delay loop to cause an increase in the VCDL delay. Similarly, if the VCDL delay is more than 360 degrees, the control signal voltage is changed in the opposite direction, to cause a decrease in the VCDL delay. The net effect is such that, after a random startup condition, the loop goes through an acquisition process where the delay is adjusted up or down to finally reach the desired delay (i.e., 360 degrees) in the “locked” state. In this state, minor changes in the input clock signal would be tracked by the phase delay loop to keep the delay about 360 degrees.

Prior art phase delay lines operate to determine delay by comparing the phase of the delay-line output with the phase of the input clock, and detecting the phase difference between those two signals. This leads to the result that such a prior-art phase detector would detect the same phase difference whether the actual delay through the delay line is 360 degrees or a multiple of 360 degrees—e.g., 720 degrees, 1080 degrees, and so on. This could result in a false locking of the delay line to multiples of the input clock period. For example, such a phase detector based on input and output phase might correctly produce a delay loop lock in the exemplary case illustrated schematically in FIG. 2, where the input clock signal has frequency f and period T=1/f, to produce a delay D=T. However, that same phase detector will also produce a lock control signal for a delay equal to 2T, the case illustrated schematically in FIG. 3. (Note that the control signal will be a substantially constant voltage in the phase lock cases illustrated in FIGS. 2 and 3).

### SUMMARY OF THE INVENTION

A new method is provided for detecting and controlling the phase-delay in a delay line. The proposed invention accomplishes this by first determining a logic state of an output signal of at least two stages of the delay line, including at least one interior stage, and then generating a control signal for the delay line as a function of the determined logic states. According to the method of the invention, the logic states of the at least two stages of the delay line are indicative of a phase difference between an input signal to the delay line and an output signal therefrom.

In another embodiment of the invention, logic states for a plurality of interior stages of the delay line are sampled and a control signal is generated to cause an increase in the delay through the delay if the logic states for all of the sampled interior stages are at logic 0. Alternatively, if the logic state for at least one of the sampled interior nodes is not at logic 0, a control signal is generated to cause a decrease in the delay through the delay line.

In a still further embodiment of the invention, an improved delay line apparatus is provided and includes output taps established at the final stage of the delay line and at least one of the interior stages of the delay line. The improved delay line apparatus further includes delay detection means operable to sample the logic states for the final delay line stage and the at least one interior stage, and to generate a control signal as a function of logical combinations found to exist at the sampled stages. The control signal operates in turn to effect an appropriate change in the delay through the delay line.

### BRIEF DESCRIPTION OF THE DRAWINGS

FIG. 1 provides a schematic depiction of a typical VCDL in a control loop.

FIG. 2 provides a schematic depiction of a simple delay locking in a calibration loop where the input-to-output phase difference is 360 degrees.

FIG. 3 provides a schematic depiction of a simple delay locking in a calibration loop where the input-to-output phase difference is an integer multiple of 360 degrees.

FIG. 4 provides a schematic depiction of an illustrative 32-stage voltage-controlled delay line.

FIG. 5 provides a schematic depiction of the illustrative VCDL of FIG. 4 for the case that delay through the delay line is greater than a desired delay.

FIG. 6 provides a schematic depiction of the illustrative VCDL of FIG. 4 for the case that delay through the delay line is less than a desired delay.

FIG. 7 provides a schematic depiction of the illustrative VCDL of FIG. 4 for the case that delay through the delay line is less than one-half an input clock cycle.

FIG. 8 provides a schematic depiction of the illustrative VCDL of FIG. 4 for the case that delay through the delay line is greater than a 1.5 input clock cycles.

FIG. 9 illustrates the steps of an illustrative embodiment of the invention in flow chart form.

FIG. 10 provides a schematic depiction of the illustrative VCDL of FIG. 4 for the case that delay through the delay line is between 1 and 1.5 input clock cycles.

FIG. 11 schematically illustrates phase delay ranges relevant to internal node selection according to the invention for one possible delay range, given an output stage at logic 0.

FIG. 12 schematically illustrates phase delay ranges relevant to internal node selection according to the invention for another possible delay range, given an output stage at logic 0.

FIG. 13 schematically illustrates phase delay ranges relevant to internal node selection according to the invention for one possible delay range, given an output stage at logic 1.

FIG. 14 schematically illustrates phase delay ranges relevant to internal node selection according to the invention for another possible delay range, given an output stage at logic 1.

FIG. 15 depicts schematically a phase-delay detector logic circuit arranged to carry out an embodiment of the methodology of the invention.

### DETAILED DESCRIPTION OF THE INVENTION

The invention disclosed herein is directed to a method for causing a delay line to lock up only in the circumstance of the phase delay between the input and output of the delay line being of a specified magnitude, and not at a delay represented by the specified delay magnitude plus some multiple of 360 degrees. In the embodiment described hereafter, that specified delay is taken to be 360 degrees; however, it should be understood that the principles of the invention apply in general to any desired phase-delay. For example, a different calibration loop might be designed to lock up in the circumstance of the phase delay between the input and output of the delay line being 180 degrees. The methodology of the invention would still apply to guarantee that the locking phase-delay is 180 degrees and not 180 degrees plus some multiple of 360 degrees.

The invention is described hereafter in terms of an exemplary voltage controlled delay line comprised of 32 stages, but it should be understood that the principles of the invention apply to a VCDL of any number of stages. The invention is also described hereafter in terms of the input, output and intermediate VCDL signals being ‘square wave’ clock signals, and it should be similarly understood that the principles of the invention apply to signals of other shapes (including sinusoidal signals) that contain timing information. Furthermore, the invention is described in terms of the signals at selected nodes of the delay line being sampled at the rising edge of the input clock signal. However, it should be understood that the principles of the invention apply to a different implementation that samples the monitored signals at the falling edge of the input clock signal. It is intended, as well, that the principles of the invention be applied to other delay line implementations for which delay is adjusted in response to a control signal established as a function of phase difference between an input and an output signal.

As a preface to discussion of the methodology and structure for the invention disclosed herein it is useful to first consider a typical VCDL operated according to the techniques of the prior art, and then to show how the limitations of that arrangement are addressed and overcome by the invention.

An exemplary voltage-controlled delay line consisting of 32 identical delay stages is schematically illustrated in FIG. 4. As will be apparent from the figure, the input to and output from the VCDL are labeled, respectively, node 0 and node 32. The output from intermediate stages of the VCDL (and input to an immediately following stage) are indicated as nodes 1, 2 . . . .

As noted above, such prior-art delay lines operate to compare the phase of the output of the delay line with the phase of the input clock signal to detect a phase difference between such input and output signals. For the illustrative VCDL of FIG. 4, such a phase comparison would be made between the input signal at node 0 and the output signal at node 32. That prior-art phase detection arrangement typically samples the output signal synchronous with the transition of the input waveform from logic 1 to logic 0 (or vice versa).

For the steady-state case of the delay through the delay line being maintained substantially at the desired one clock-cycle delay, the control system can be expected to operate to pulse the VCDL delay alternately in one direction and then the other (i.e., increase, then decrease delay repeatedly, or vice versa). For a control loop with negligible latency, the delay will increment and decrement at successive sample times. Accordingly, in that steady-state case, the output reading will generally alternate between logic 1 and logic 0 for successive clock cycles. In general, for a control loop with L cycles of latency, the alternating pulse width will be equal to L clock cycles.

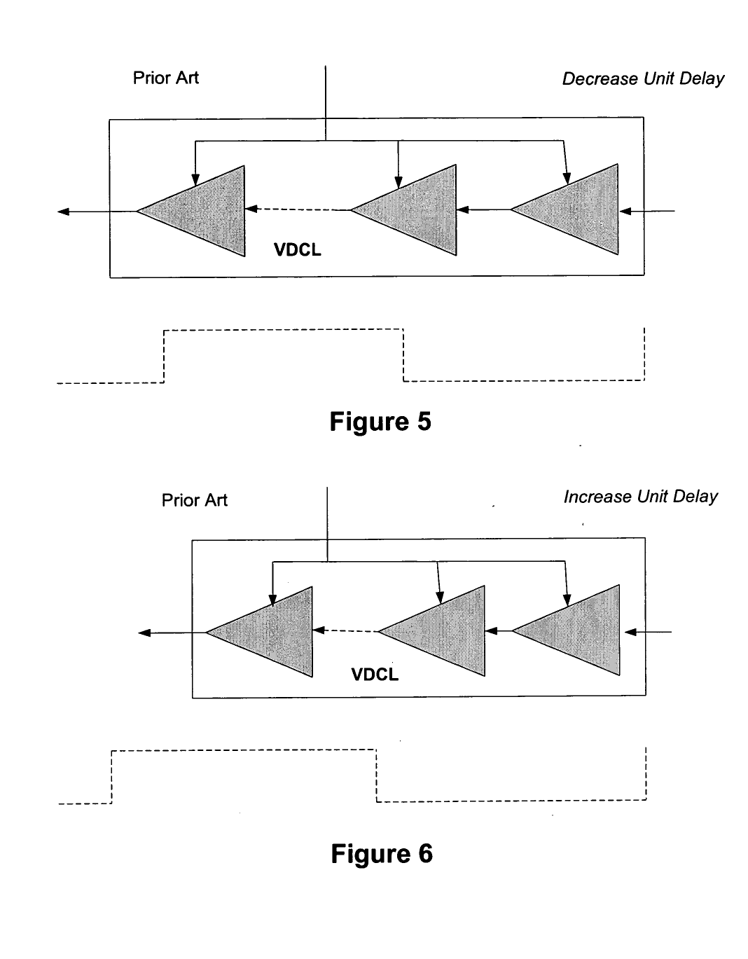

The cases of the delay though the delay line being greater and lesser than the desired one clock-cycle (360 degree) delay for this exemplary VCDL are illustrated in FIGS. 5 and 6. With reference to FIG. 5, showing the case of the total delay being greater than desired, the clock signal measured at the output node of the delay line will, at the output sample time, be at a point in the clock cycle between the beginning of the high state and the transition back to the low state. Thus, as shown in the figure, the delay line output will be at logic 1. Similarly, in the case of the total delay being less than desired, illustrated in FIG. 6, the delay line output reading will occur at a point in the clock cycle after the transition to the low state, but before a return to the high state (where such a return to the high state would correspond to a delay through the VCDL of greater than 1.5 times the clock period). The delay line output will, in this case, accordingly be at logic 0.

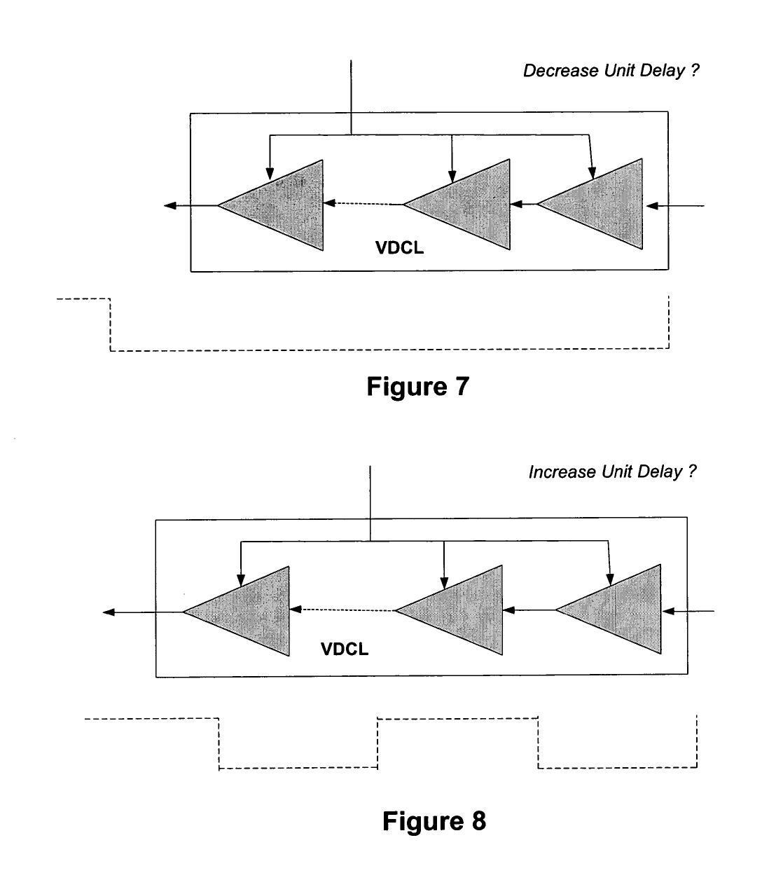

As is well known, the prior-art methodology of comparing the phases of the input and output signals of a delay line to detect a phase difference between those signals provides a correct result only if the total delay is limited to a range between one half the clock period and 1.5 times the clock period. Outside these limits, i.e., less than one half the clock period and more than 1.5 times the clock period, this approach cannot be relied on for correct detection of the delay through the delay line, as explained below. The cases of the delay through the delay line being less than one-half the input clock period and greater than 1.5 times the clock period are illustrated schematically in FIGS. 7 and 8, respectively. In the case shown in FIG. 7, the output stage would be at logic 0 at the sample time and the phase detector would incorrectly conclude that the delay needs to be decreased, when, in fact, the total delay is already less than half the input clock period. Similarly, for the case shown in FIG. 8, the output stage would be at logic 1 at the sample time, and the phase detector would wrongly conclude that the delay needs to be increased, when, in fact, the delay is already more than 1.5 times the input clock period.

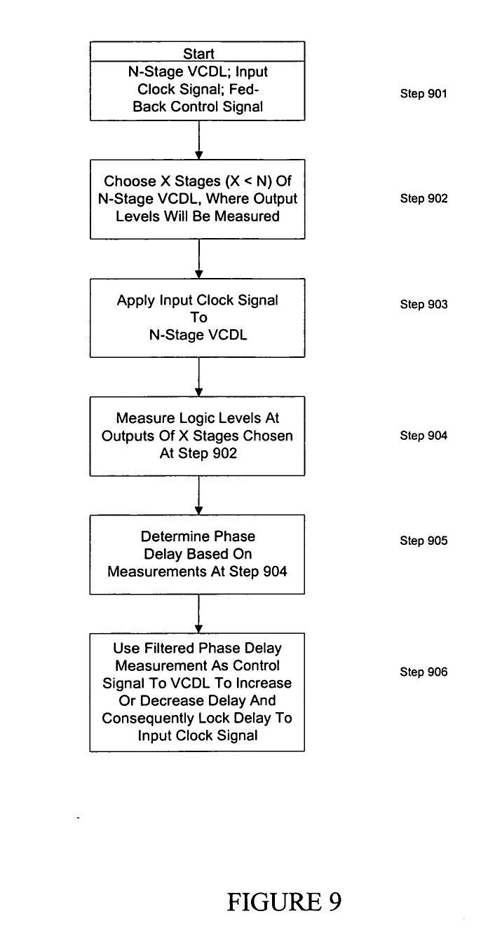

The method of the invention operates to overcome the described deficiencies of prior-art delay lines, and will be described hereafter in respect to embodiments illustrated in FIGS. 9-15.

The overall process of the invention methodology is illustrated by the flow chart of FIG. 9. With reference to that figure, the process begins at step 901, where the structural environment for the described embodiment is set out—i.e., the invention embodiment depicted in FIG. 9 is described in terms of an application of the method of the invention to an N-stage VCDL having an input clock signal and a fed-back control signal.

At step 902, a number of the stages, X, of the N-stage VCDL are selected (X<N) at which output logic levels will be measured in the course of carrying out the method of the invention. In most VCDL applications (other than the case of ideal input signal parameters, discussed below), one of the selected stages will be the output stage of the VCDL, with the remaining X−1 selected stages being interior stages. This configuration will be assumed for the remainder of the description of the FIG. 9 embodiment.

Having selected the X stages for logic level measurements, an input clock signal is applied to the VCDL at step 903 and measurements made of the logic level outputs at the selected stages at step 904. The logic level measurements so made are then operated on by the invention at step 905, as described in detail below, to determine the phase delay of the VCDL and to provide a control parameter for the fed-back control signal to correct any deviation from the desired delay for the VCDL, as shown at step 906.

The determination of phase delay through the delay line, as illustrated globally in step 905 of FIG. 9, is believed to be best illustrated with an exemplary embodiment, using only two stages at which the output will be measured (X=2). Following the description of that illustrative embodiment, a generalized embodiment will be described for case of X (the number of stages at which the output is measured and processed) being any arbitrary number less than the total number of stages comprising the VCDL. As noted above, the exemplary embodiment is based on an illustrative VCDL having N=32 stages.

For this exemplary embodiment, logic level measurements are made at only two VCDL stages, and those stages are selected as stage 32, which is the output stage of the exemplary 32 stage VCDL of the embodiment (and indicated as Node 32 in the schematic depiction of that exemplary case in FIG. 4), and stage 16 (the logic level measurement point thereof being hereafter designated as Node 16) which will be the mid-point of that exemplary VCDL embodiment. As will be seen below, the selection of the particular stage from the interior of the VCDL is somewhat arbitrary within a range about the VCDL mid-point.

In carrying out the method of the invention, and particularly steps 904 and 905 of FIG. 9, the output of the VCDL, (node 32 for the illustrative embodiment), is initially sampled. As will be apparent, that VCDL output signal can have one of two logic states: “0” or “1.” The successive steps in the invention methodology depend on which of those two logic states is found at the VCDL output, and each such initial logic state is considered hereafter in turn.

Consider first the case of the measurement at the output of the VCDL being at logic state 0. In this case there are two possible phase-delay resultants. One, the delay through the VCDL may be one-half of a clock period, or less, the circumstance depicted in FIG. 7. In this phase-delay case, it can be readily observed from FIG. 7 that the output of all of the nodes of the VCDL would be at logic 0.

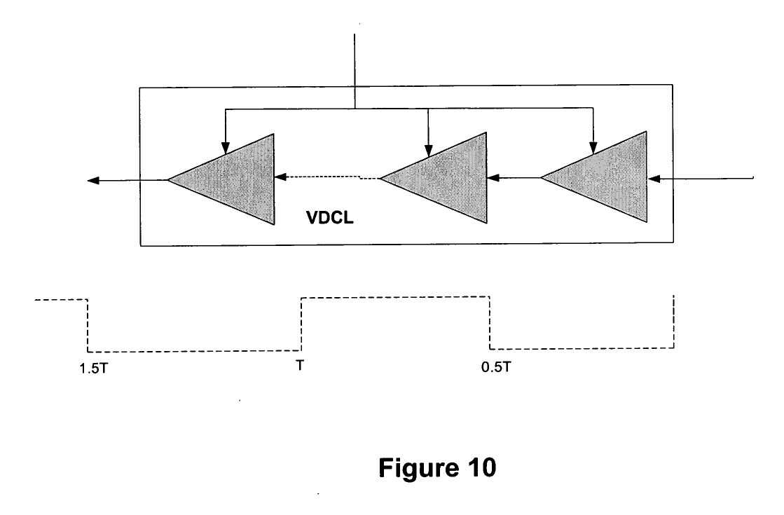

Alternatively, the circumstance of the delay through the VCDL being between 1 and 1.5 times the clock period also produces a VCDL output at logic 0. This delay circumstance is schematically depicted in FIG. 10. It can be observed from FIG. 10 that, for this delay circumstance, a number of nodes on either side of the stage at the center of the VCDL (i.e., stage N/2, or stage 16 for the described configuration) will be at a logic-1 state. Accordingly, it can be seen that the selection of the interior stage to monitor for this embodiment is not critical so long as it chosen within the range of the expected logic-1 state generally occurring through the middle range of VCDL stages (recall that the logic state was expected to be 0 for all stages in the first case discussed above). For this exemplary embodiment, VCDL stage N/2 (16) is selected for the interior monitoring point as the approximate mid-point of the range of logic 1 states for the delay case illustrated in FIG. 10.

With this background, it can readily be seen that, by sampling the logic state at node N/2 of the VCDL, one can readily resolve the prior-art ambiguity as to which one of the two possible phase-delay circumstances corresponds to the 0 logic state found at the VCDL output. That is, for the case of the VCDL output and the node N/2 output both being at logic 0, the case represented schematically in FIG. 7, it will be known that the phase-delay through the VCDL is less than or equal to one-half of a clock period, and accordingly that the delay through the VCDL must be increased. Similarly, for the case of the VCDL output being at logic 0 and the node N/2 output being at logic 1, the case represented schematically in FIG. 10, it will be known that the phase-delay through the VCDL is between 1 and 1.5 clock periods, and accordingly that the delay through the VCDL must be decreased. On the basis of such determinations—i.e., with VCDL output at logic 0, node N/2 being at logic 0 calling for increased delay and at logic 1 calling for decreased delay, appropriate control signals may be generated in a conventional manner to produce the desired change in the total delay through the VCDL.

Consider now the possible phase-delay circumstances that cause the output of the VCDL to be at the logic-1 state. The first is a phase delay through the VCDL of greater than one-half a clock cycle but less than the full clock cycle, which is illustrated schematically in FIG. 5. Alternatively, an output logic-1 state will also be produced by a delay through the VCDL greater than 1.5 clock cycles but less than two clock cycles, as illustrated schematically in FIG. 8. Just as with the first case where the output of the VCDL was at logic 0, the ambiguity between the two phase delay circumstances that both cause a logic-1 state at the VCDL output can be resolved according to the method of the invention by observance of the logic state at VCDL node N/2.

As can be seen from the figures, in the first case (FIG. 5), the logic state of stage outputs near the middle of the VCDL will all be at logic 1, while for the second case (FIG. 8), stage outputs near the middle of the VCDL will all be at logic 0. Thus by also measuring the logic state at node N/2, the true delay through the VCDL can be determined according to the following rule. If the logic state at both node N/2 and the VCDL output is logic 1, the delay through the VCDL is more than 1 clock period, and should therefore be caused to decrease. If the logic state at node N/2 is logic 0 when the logic state at the VCDL output is logic 1, the delay through the VCDL is less than one clock period, and accordingly the total VCDL delay should be increased. On the basis of such determinations (i.e., with VCDL output at logic 1, node N/2 being at logic 1 calls for decreasing the phase-delay and node N/2 being at logic 0 calls for increasing the phase-delay), appropriate control signals may be generated in a conventional manner to produce the desired change in the total phase-delay through the VCDL.

It follows therefore that, by obtaining the logic state for at least two stages of the VCDL, the method of the invention overcomes the ambiguity resulting in measurements made only at the output of the VCDL, as occurs with the prior art. Note though that, for the embodiment just described where logic state measurements are obtained at only the VCDL output node and one interior node, a correct result is assured only for the case that the total delay through the VCDL is not greater than two clock periods. The premise of the invention can, however, be extended to assure a correct result for a larger range of total delay through the VCDL. Sampling the logic state at internal node N/4 (node 8 in the illustrated case) in addition to sampling internal node N/2 (node 16), allows correct operation of the phase-delay detector for a total delay range of four clock periods. Sampling internal nodes N/2, N/4 and N/8, allows correct operation over eight clock periods of total delay. In the limit for the illustrated 32 stage VCDL, sampling internal nodes 16, 8, 4, 2 and 1, allows correct operation up to 32 clock periods of total VCDL delay.

Prior to discussing the details of such an extension of the invention premise to the consideration of additional interior nodes, it is useful to note that, in the case of an ideal input signal (i.e., an ideal 50-50 duty cycle of the input clock signal, perfectly symmetrical positive and negative clock pulses and no cycle-to-cycle clock jitter) and an ideal delay line (no mismatch between different delay stages in the delay line), the negative clock transition at internal node 16 is exactly concurrent with the positive transition at node 32. In that circumstance, given monitoring of internal node 16, it would not be necessary to also independently monitor node 32. In most applications, however, such an ideal input signal and ideal delay line are unlikely to be realized and variations from the exact 50-50 clock duty cycle and from a perfect delay line will necessitate independent monitoring of node 32.

In describing the multiple interior node embodiment of the invention, an explanatory algorithm for the case of an ideal input signal and an ideal delay line (as described above) is first developed because it will help lead to an understanding of the more general algorithm for non-ideal circumstances which is subsequently considered. For that ideal case, an algorithm for controlling delay in a delay line according to the method of the invention, generalized for an arbitrary number of stages in the delay line, is presented below. It should be understood that the variable “N” in the algorithm is equal to the number of stages of the delay line. The algorithm is:
Step 1: Determine the maximum total delay possible in the particular delay line implementation being used.
Step 2: Based on the determined range of total delay, choose (in sequence) from the following ordered sequence, a set of interior nodes to be sampled—N/2, N/4 . . . 4, 2, 1.
Step 3: Sample the chosen set of interior nodes—N/2, N/4.
Step 4: If all of the sampled nodes are at logic 0, generate a control signal indicative that delay needs to be increased.
   Otherwise generate a control signal indicative that delay needs to be decreased.
Step 5: Apply the increase/decrease control signal indications to control the delay line.
   Note that in Step 2, internal node spacing was selected to be at powers of two because this choice leads to the minimum number of nodes for monitoring, given the ideal case assumed here. The choice of internal nodes can be more closely spaced as will be discussed hereafter.

The foregoing algorithm will accurately maintain the desired delay through the N-stage VCDL for the ideal case. However, minor alterations in the number and choice of sample nodes will be required in the non-ideal case of imperfect duty cycle, clock signal jitter or imperfect delay line. In general, such alterations will be determined by an assessment of the expected non-idealities in respect to the particular operating circumstances for a given delay line. A revised algorithm addressed to the case of such a non-ideal input signal is developed below, but it is useful to first catalog the logic states for the output and selected interior nodes in respect to various phase delays expected to be experienced by the N-stage delay line.

If the input clock duty-cycle is not exactly 50%-50% (for instance, 45%-55%), monitoring of the output node of the last stage of the VCDL (i.e., Node N) becomes necessary (as discussed above). Based on the logic state of node N, an initial decision can be made broadly characterizing the possible phase of the output signal. If node N is logic-0, the output signal phase must be within one of the following ranges: 0-180 degrees or 360-540 degrees or 720-900 degrees and so on. Conversely, if node N is logic-1, the output signal phase must be within one of the following ranges: 180-360 degrees or 540-720 degrees or 900-1080 degrees and so on. In this manner, based on the observed logic-value of node N, the phase possibility of the output signal can be narrowed to one of two mutually exclusive sets of ranges. (Note that the phase ranges described herein are referenced using their ideal range end-points. However, circuit non-idealities lead to some phase uncertainty in the exact phase of the range end-points (as will be discussed in more detail hereafter).

Recognizing this correlation between possible phase delay range and the state of the output node, the further selection of nodes to be considered can be made dependent on the monitored value of node N. The set of internal nodes, A_{N=0}, B_{N=0}, C_{N=0} . . . , selected when node N is at logic-0 may be different from the set of internal nodes, A_{N=1}, B_{N=1}, C_{N=1} . . . , selected when node N is at logic-1. The choice of the interior nodes to be monitored (indicated in the algorithm below as nodes A_{N=0}, B_{N=0}, C_{N=0} . . . and nodes A_{N=1}, B_{N=1}, C_{N=1} . . . ) will be made in respect to consideration of the circuit-specific conditions and the consequent expectations of clock duty cycle variation, clock jitter and mismatch between the different individual stages of delay in the delay line.

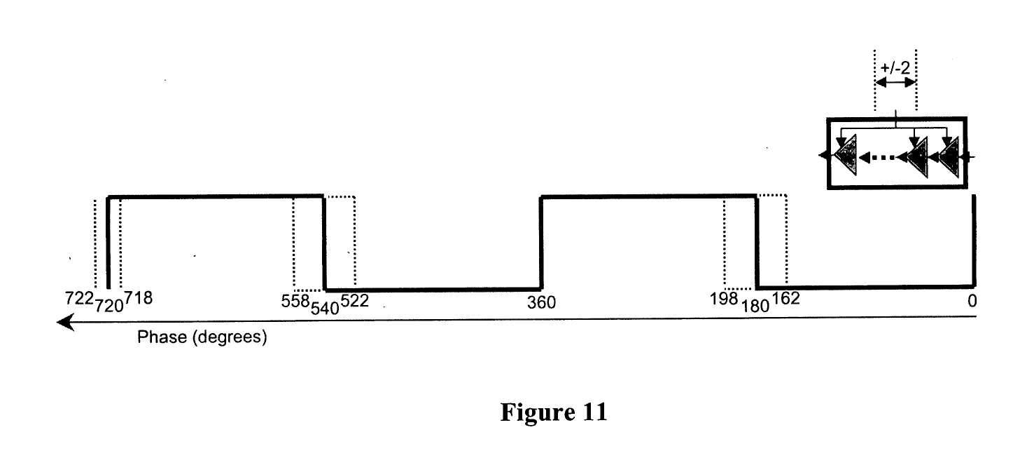

The process for selection of the monitored interior nodes is well illustrated by the following exemplary case. Preliminarily to consideration of the example, however, comment is merited respecting the limits of phase delay ranges considered. In FIGS. 11 thru 14, which depict delay ranges relevant to the example, edges of the phase delay waveforms are characterized by both solid and dashed lines. The solid lines at the waveform edges indicate the ideal clock edges and the dotted lines indicate the edge uncertainty due to one or more of the non-idealities described above. The particular magnitude of the phase-delay uncertainty will vary from implementation to implementation and will depend on the nature and magnitude of the different non-idealities in the particular implementation.

Consequently, the placement of the dotted lines in FIGS. 11-14 may be, different for a different particular implementation than shown here. A careful analysis of the implementation-specific non-idealities will allow a person skilled in the art to detemmine the placement of the dotted lines in FIGS. 11-14 for a given particular implementation. For the exemplary case considered, note that the phase uncertainty in the positive edges at 720 degrees and above arises from the cycle-to-cycle clock signal jitter (assumed here to be ±0.5% or, approximately ±2 degrees). The uncertainty in the negative edges arises from the uncertain duty-cycle variation from ideal 50%-50% (assumed here to be ±5% or, equivalently, ±18 degrees). Moreover, when considering the phase at any internal node (1 thru 31) in the delay line, there is an additional uncertainty due to the mismatch between different stages in the delay line (assumed here to be ±5% or, approximately, ±2 degrees).

As a starting point, note that the example is based on a 32 stage delay line (N=32) and that the logic level of node N is monitored at the instant that there is a positive transition at the input to the delay line (i.e., at node 0). This logic level may be either logic-0 or logic-1, and those node N logic states are hereafter considered seriatim. First, consider the case that node N is logic-0. As discussed above, this logic state for node N indicates that the output signal phase must be within one of the following ranges: 0-180 degrees or 360-540 degrees or 720-900 degrees and so on. For the case of the delay through the delay line being in the range 0-180 degrees, as depicted in FIG. 11, it can readily be seen from the figure that all internal nodes are logic-0. It follows that a determination of the logic state of any internal node to be logic-1 necessarily rules out the possibility that the output signal phase delay is in the range 0-180 degrees.

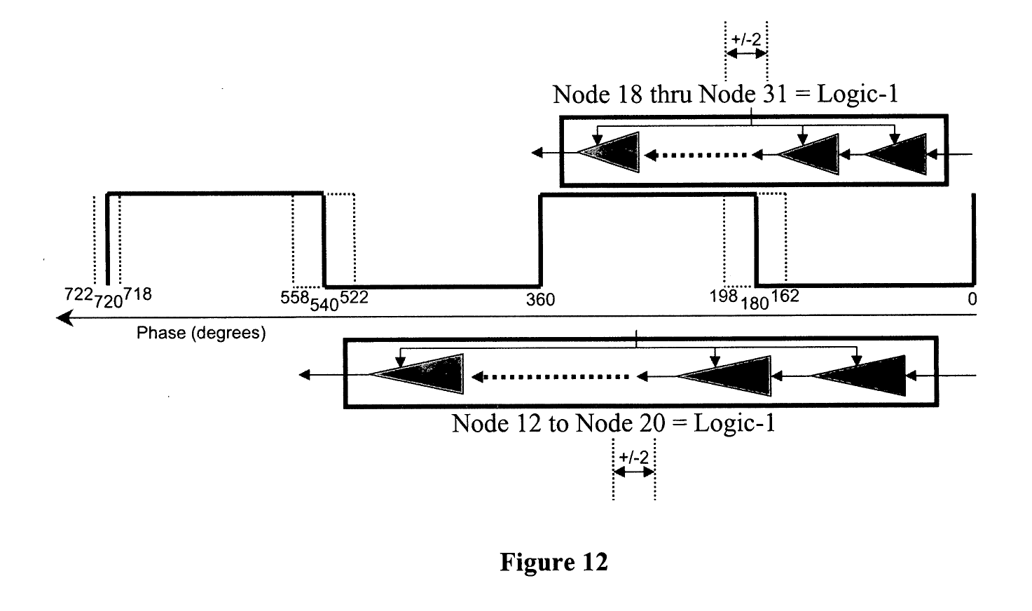

Consider now the case where the output signal phase is in the range 360-540 degrees, as illustrated schematically in FIG. 12. It can be seen in FIG. 12 that, in the worst case, phase delays of 198 to 360 degrees are guaranteed to correspond to logic-1 with certainty. At one extreme of the range, output node 32 is at phase=360 degrees. Note that, ideally, all internal nodes would be linearly spaced with respect to phase from 0 degrees to 360 degrees. However, due to mismatch between different individual delay stages in the delay line, the actual phase at an internal node may be displaced by at most 2 degrees from the ideal. With these considerations, it is clear that when output node 32 is at phase=360 degrees, internal nodes 18 thru 31 are all certainly logic-1. At the other extreme of the range, output node 32 is at phase=558 degrees and nodes 12 thru 20 are all certainly logic-1. Within these two extremes (phase of output node 32 in the range 360-540 degrees), it follows that nodes 18 thru 20 are guaranteed to be certainly logic-1. Thus, one of these internal nodes, e.g. node 19, would be selected for monitoring.

Recall that, for this aspect of the example analysis, output node 32 is assumed to be at logic-0. Accordingly, if node 19 is also logic-0, a determination is made that the output signal phase is in the range 0-180 degrees. Alternatively, if node 19 is logic-1, the determination is made that the output signal phase is in the range 360-540 degrees. Since the desired output signal phase is exactly 360 degrees, in the former case the unit-delay in the delay line is less than the desired 360 degrees and will be increased, and in the latter case the unit-delay in the delay line is more than the desired 360 degrees and will be decreased.

Using the same method as described in the foregoing example, one can successively consider output signal phase in the range 720-900 degrees, 1080-1260 degrees and so on up to the maximum total delay possible in the particular delay line implementation being used, and thereby choose internal nodes to monitor for each phase range considered. Some selected internal nodes will satisfy multiple ranges of output signal phase and so, the total number of internal nodes chosen for monitoring will be less than or equal to the number of possible phase ranges above 360 degrees. This analysis will establish all the internal nodes to be monitored—A_{N=0}, B_{N=0}, C_{N=0} . . . when node N is logic-0.

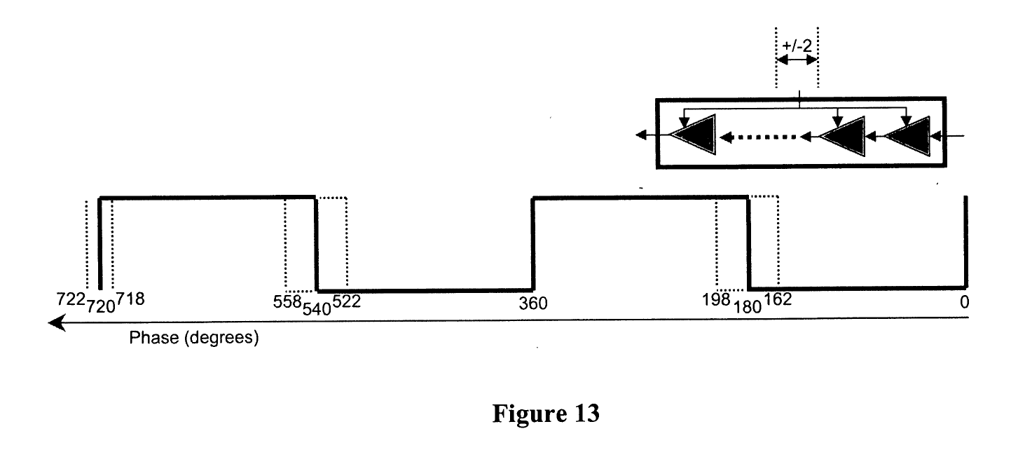

To complete the example analysis, the case of the output stage, node N, being at logic-1 is now considered. Recall, from a preceding discussion, that for this logic state at node N, the output signal phase must be within one of the following ranges: 180-360 degrees or 540-720 degrees or 900-1080 degrees and so on. A critique of the interior node selection process for this case is usefully considered in connection with FIG. 13. As with FIGS. 11 & 12, the solid lines in the phase delay waveform of the figure indicate the ideal clock edges and the dotted lines indicate the edge uncertainty due to circuit non-idealities and consequent deviations from the ideal case. It can readily be seen from the figure that, for the exemplary 32-stage delay line, if the output signal phase is in the range 180-360 degrees, internal nodes 1 thru 14 are all logic-0 with certainty. From this one can conclude that a determination of the logic state of any internal node 1 thru 14 to be logic-1 necessarily rules out the possibility that the output signal phase is in the range 180-360 degrees.

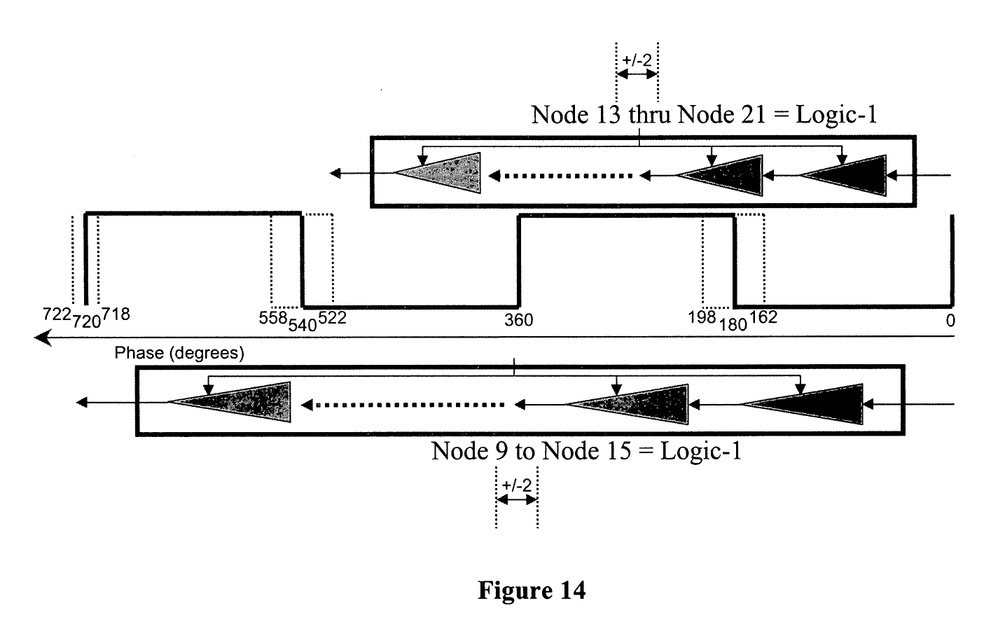

Consider now the case where the output signal phase is in the range 540-720 degrees, as illustrated schematically in FIG. 14. It can be seen in that figure that, in the worst case, phase delays of 198 to 360 degrees are guaranteed to correspond to logic-1 with certainty. At one extreme of the range, output node 32 is at phase=522 degrees. As previously noted, ideally, all internal nodes would be linearly spaced with respect to phase from 0 degrees to 522 degrees. However, due to mismatch between different individual delay stages in the delay line, the actual phase at an internal node may be displaced by at most ±2 degrees from the ideal. With these considerations, it is clear that when output node 32 is at phase=522 degrees, internal nodes 13 thru 21 are all certainly logic-1. At the other extreme of the range, output node 32 is at phase=722 degrees and nodes 9 thru 15 are all certainly logic-1. Within these two extremes (i.e., phase of output node 32 being in the range 540-720 degrees), it follows that nodes 13 thru 15 are guaranteed to be certainly logic-1. Thus, either node 13 or node 14 would be selected for monitoring. For the following discussion it is assumed that node 14 was selected.

Recall that, for this aspect of the example analysis, output node 32 is assumed to be at logic-1. Accordingly, if node 14 is also logic-0, a determination is made that the output signal phase is in the range 180-360 degrees. Alternatively, if node 14 is logic-1, the determination is made that the output signal phase is in the range 540-720 degrees. Since the desired output signal phase is exactly 360 degrees, in the former case the unit-delay in the delay line is less than the desired 360 degrees and will be increased and in the latter case the unit-delay in the delay line is more than the desired 360 degrees and will be decreased.

In the same manner, one can successively consider output signal phase in the range 900-1080 degrees, 1260-1440 degrees and so on up to the maximum total delay possible in the particular delay line implementation being used and choose an internal node (in the range 1 thru 14) to monitor for each phase range considered. Again, some selected internal nodes will satisfy multiple ranges of output signal phase and so, the total number of internal nodes chosen for monitoring will be less than or equal to the number of possible phase ranges above 360 degrees. This analysis will establish all the internal nodes to be monitored—A_{N=1}, B_{N=1}, C_{N=1} . . . when node N is logic-1.

The process for choosing interior nodes for monitoring in respect to particular implementation-specific non-idealities and particular operating circumstances for a given delay line will be readily apparent to those skilled in the art from the foregoing example, and need not be further discussed here. Consequently, to address deviations from the ideal case, the generalized N-stage delay line algorithm above, which was developed in respect to such ideal circumstances, would be modified to have the following general structure:
Step 1: Determine the maximum total delay possible in the particular delay line implementation being used and assess the expected circuit non-idealities. Based on these determinations, select the two sets of internal nodes to be monitored, A_{N=0}, B_{N=0}, C_{N=0} . . . and A_{N=1}, B_{N=1}, C_{N=1} . . .
Step 2: Sample the delay line output node (Node N).
   If node N=logic-1 skip to Step 4. If node N=logic-0, continue to Step 3.
Step 3: Sample nodes A_{N=0}, B_{N=0}, C_{N=0} . . .
   If nodes A_{N=0}, B_{N=0}, C_{N=0} . . . are all logic 0, generate a control signal indicative that delay needs to be increased.
   Otherwise generate a control signal indicative that delay needs to be decreased.
   Skip to Step 5.
Step 4: Sample nodes A_{N=1}, B_{N=1}, C_{N=1} . . .
   If nodes A_{N=1}, B_{N=1}, C_{N=1} . . . are all logic 0, generate a control signal indicative that delay needs to be increased.
   Otherwise generate a control signal indicative that delay needs to be decreased.
Step 5: Apply the increase/decrease control signal indications to control the delay line.

An application of this general algorithm structure to the exemplary case described above would be carried out as follows. Recall, initially, that the example assumes a 32-stage delay line—i.e., N=32. For this particular application, it will be assumed that the maximum possible phase-delay for the implementation under consideration is 720 degrees (or, equivalently, 2 clock cycles). Under this assumption, one only needs to monitor one internal node, A_{N=0}, for the case of node 32 (the output node) being logic-0 and one internal node, A_{N=1}, for the case of node 32 being logic-1. Also, recall that, for the case node 32=logic-0, node 19 was chosen for monitoring and, for the case node 32=logic-1, node 14 was chosen for monitoring. Hence, for this exemplary application, A_{N=0} is 19 and A_{N=1} is 14. Using the nomenclature N32, N19 and N14 for labeling the monitored logic state (0 or 1) at nodes 32, 19 and 14 respectively, the general algorithm structure described above translates to the following logic function for this exemplary application:

IncreaseUnitDelay=N32′.N19′+N32.N14′

where, pursuant to standard terminology in the electronic art, the apostrophe, ′, denotes a logical NOT function, the dot, ., denotes a logical AND function and the plus, +, denotes a logical OR function. The variable, IncreaseUnitDelay=0 is interpreted as a signal to decrease unit delay in the delay line and IncreaseUnitDelay=1 is interpreted as a signal to increase unit delay.

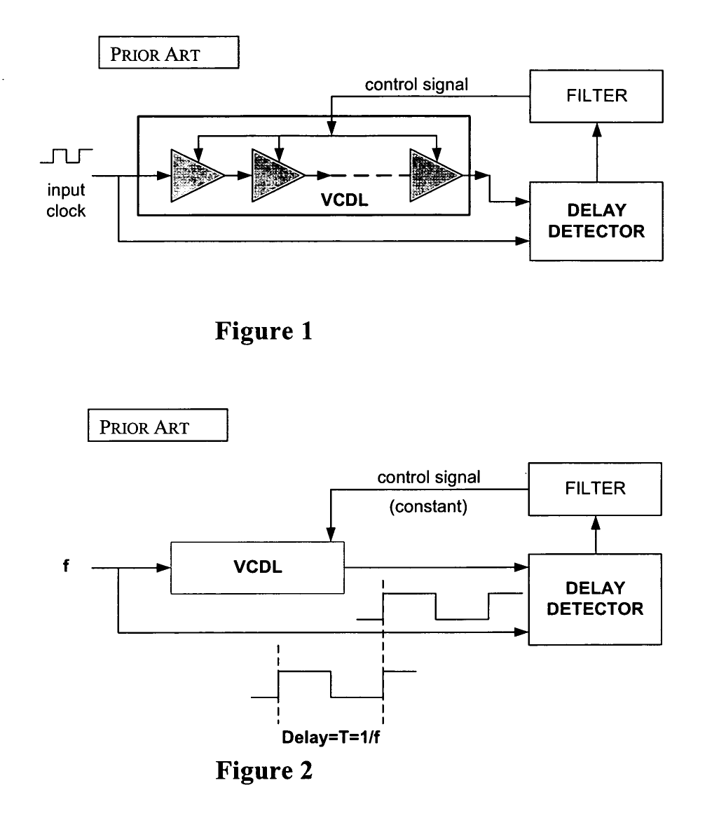

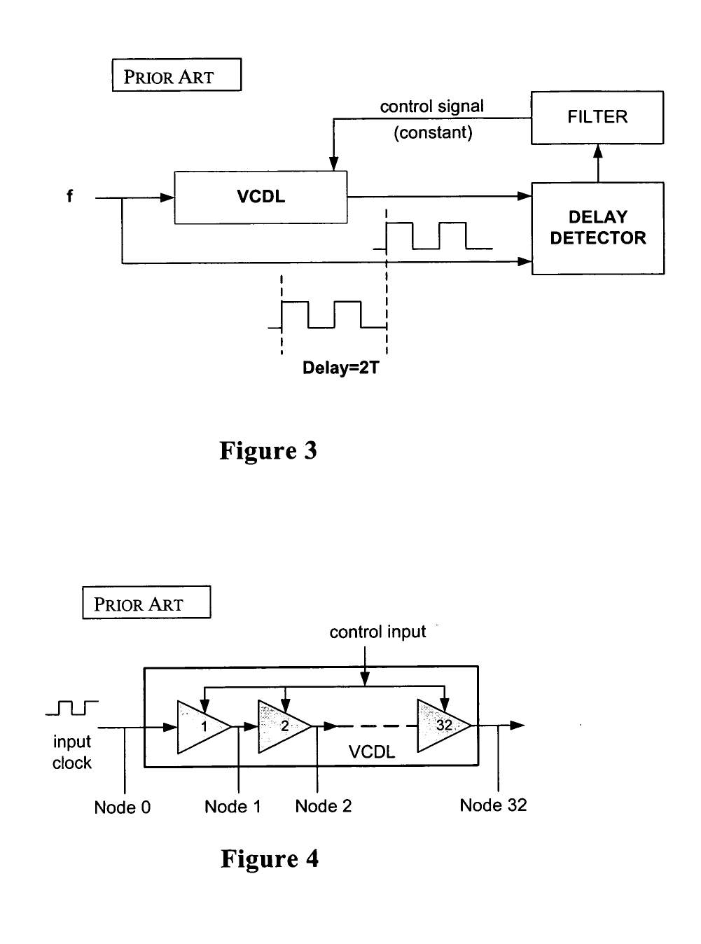

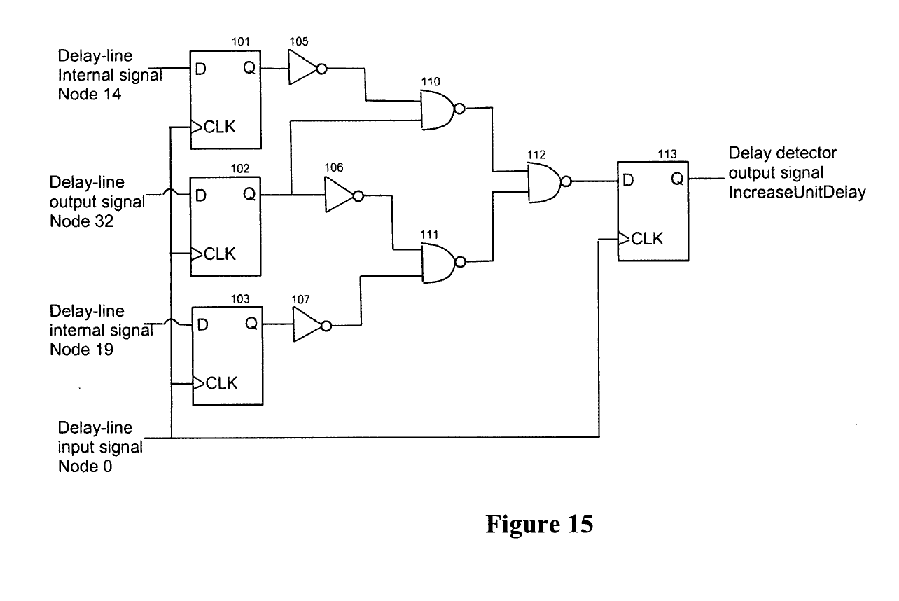

A phase-delay detector logic circuit arranged to carry out the methodology of the exemplary embodiment described above is schematically depicted in FIG. 15. Note that the circuit arrangement of FIG. 15 generally corresponds to the delay detector block of FIG. 1, but is uniquely arranged to carry out the exemplary embodiment of the methodology of the invention described herein.

Note also that the logic function presented above for this exemplary case is logically equivalent to the following alternate logic function:

IncreaseUnitDelay=((N32′.N19′)′.(N32.N14′)′)′

and that the logic circuit arrangement of FIG. 15 is based on an implementation of this alternate logic function.

Considering particularly the logic circuit arrangement of FIG. 15, a plurality of Master-slave Flip-flops (101, 102 & 103) are provided as input devices to sample the logic state of designated delay line stages synchronous with the input clock signal (rising edge of the input clock signal for the exemplary case described), and to provide an output signal corresponding to respective sampled logic states to an equal plurality of logical NOT gates (105, 106 & 107). It will be understood that, while the number of Master-slave Flip-flops (and NOT gates receiving the output thereof) for the exemplary embodiment depicted in FIG. 15 is 3, corresponding to sampling the logic state of nodes 14, 19 and 32 of the delay line, in the general case, the number of Master-slave Flip-flops and NOT gates applied in the delay detector logic circuit of the invention would be equal to the number of monitored interior and exterior nodes for the actual application to which the invention is applied.

NAND gates 110 and 111 in FIG. 15 are arranged to receive either the output of Master-slave Flip-flop 102 (representing the sampled logic state for node 32) or its logical inverse (output of NOT gate 106) for NANDing with the outputs of NOT gates 101 and 103 respectively (logical inverses of sampled logic states for nodes 14 and 19). The outputs of NAND gates 110 and 111 are in turn provided as inputs to NAND gate 112, whose output is provided as the feedback control signal to the delay line, via Master-slave Flip-flop 102 synchronous with the input clock signal.

Herein, the inventor has disclosed a new and improved method for determining a correct phase delay through a delay line. Numerous modifications and alternative embodiments of the invention will be apparent to those skilled in the art in view of the foregoing description. In particular, it should be understood that, while the invention has been described in terms of a voltage control delay line, the principles of the invention will equally apply for other forms of delay lines involving feedback control.

Accordingly, this description is to be construed as illustrative only and is for the purpose of teaching those skilled in the art the best mode of carrying out the invention and is not intended to illustrate all possible forms thereof. It is also understood that the words used are words of description, rather that limitation, and that details of the structure may be varied substantially without departing from the spirit of the invention, and that the exclusive use of all modifications which come within the scope of the appended claims is reserved.

1. A method for controlling delay in a delay line comprising the steps of:
determining a logic state for at least two stages of the delay line, at least one stage being an interior stage;
generating a control signal for the delay line as a function of the determined logic states for the at least two stages of the delay line.

2. The method for controlling delay of claim 1 wherein the step of determining a logic state occurs coincident with a transition in an input signal applied to the delay line.

3. The method for controlling delay of claim 1 wherein logic states of the at least two stages of the delay line are indicative of a phase difference between an input signal to the delay line and an output signal therefrom.

4. (canceled)

5. The method for controlling delay of claim 3 wherein the step of generating a control signal operates in response to the indicated phase difference to cause the phase difference between the input and output signals to be increased if the indicated phase difference is less than a desired phase difference and to be decreased if the indicated phase difference is greater than the desired phase difference.

6. The method for controlling delay of claim 5 wherein one of the at least two stages of the delay line at which a logic state is determined is the output stage of the delay line.

7. The method for controlling delay of claim 6 wherein a logic state “0” determined at the output stage of the delay line in combination with a logic state “0” determined at the at least one interior stage is indicative that the phase difference between the input and the output signals is less than the desired phase difference.

8. The method for controlling delay of claim 6 wherein a logic state “0” determined at the output stage of the delay line in combination with a logic state “1” determined at the at least one interior stage is indicative that the phase difference between the input and the output signals is greater than the desired phase difference.

9. (canceled)

10. The method for controlling delay of claim 6 wherein a logic state “1” determined at any sampled stage of the delay line is indicative that the phase difference between the input and the output signals is greater than the desired phase difference.

11. (canceled)

12. A method for controlling delay in an N-stage delay line comprising the steps of:
selecting a plurality of interior stages of the delay line;
sampling a logic state for each of the selected plurality of interior stage nodes;
if the logic states for all of the sampled interior stage nodes are at logic 0, generating a control signal for the delay line indicative that delay needs to be increased;
if the logic state for at least one of the sampled interior stage nodes is not at logic 0, generating a control signal for the delay line indicative that delay needs to be decreased.

13. The method for controlling delay of claim 12 wherein the step of sampling a logic state occurs coincident with a transition in an input signal applied to the delay line.

14. The method for controlling delay of claim 12 wherein logic states of the delay line are indicative of a phase difference between an input signal to the delay line and the output signal.

15. (canceled)

16. The method for controlling delay of claim 12 including the further step of sampling a logic state for an output stage (Node N) of the delay line.

17. The method for controlling delay of claim 16 wherein a sampled logic state for Node N of logic 0 along with logic states for all of the sampled interior stage nodes being at logic 0 is indicative that delay through the delay line should be increased.

18. The method for controlling delay of claim 16 wherein a sampled logic state for Node N of logic 0 along with the logic state for at least one of the sampled interior stage nodes not being at logic 0 is indicative that delay through the delay line should be decreased.

19. (canceled)

20. The method for controlling delay of claim 16 wherein a sampled logic state of logic 1 for any sampled node is indicative that delay through the delay line should be decreased.

21. An apparatus for controlling timing delay between an input and an output comprising:
a plurality of delay stages arranged in a delay line to provide a total timing delay proportional to a cumulative delay through ones of said plurality of delay stages;
output taps provided at a final one of said plurality of delay stages and at least one interior delay stage, said output taps arranged to provide a logic state for each said delay stage;
delay detection means operable to sample logic states at said output taps and an input signal to said apparatus, and to generate a control signal as a function of determined logical combinations of said sampled logic states; and
means for adjusting delay through said delay line in response to said control signal.

22. The apparatus of claim 21 wherein said delay detection means further comprises:
means for providing a logical inverse of said sampled logic state for ones of said sampled output taps; and
one or more logical gates having as inputs sampled logic states or said logical inverses of said sampled logical states for said ones of said sampled output taps and providing as an output a logical combination of said inputs;
means for logically combining outputs of said one or more logical gates, wherein said control signal is generated as a function of an output of said means for logically combining.

23. A method for controlling delay in an N-stage delay line comprising the steps of:
1) determine a maximum delay possible in the N-stage delay line and select two sets of internal nodes to be monitored, A_{N=0}, B_{N=0}, C_{N=0} . . . and A_{N=1}, B_{N=1}, C_{N=1} . . . as a function of the maximum delay and expected circuit non-idealities;
2) sample the delay line output node (Node N);
if node N=logic-1 skip to step 4. If node N=logic-0, continue to step 3;
3) sample nodes A_{N=0}, B_{N=0}, C_{N=0} . . . ;
if nodes A_{N=0}, B_{N=0}, C_{N=0} . . . are all logic 0, generate a control signal indicative that delay needs to be increased;
otherwise generate a control signal indicative that delay needs to be decreased;
skip to step 5;
4) sample nodes A_{N=1}, B_{N=1}, C_{N=1} . . . ;
if nodes A_{N=1}, B_{N=1}, C_{N=1} . . . are all logic 0, generate a control signal indicative that delay needs to be increased;
otherwise generate a control signal indicative that delay needs to be decreased;
5) apply the increase/decrease control signal indications to control the delay line.

24. A delay line control loop, comprising:
a delay line, constituted by a sequence of unit delay elements that each receives an input clock signal from a previous unit delay element and produces an output clock signal that is delayed with respect to its input clock signal, the output of the last unit delay element constituting the output of the delay line;
a delay detector circuit operative to receive the input clock signal to the delay line and the output clock signals of one or more of the unit delay elements and to produce a signal indicative of a need to increase or decrease delay from the input to the output of the delay line toward to a predetermined delay value;
a control mechanism operative to either increase or decrease delay in the delay line responsive to the delay detector circuit indication;
wherein the delay detector circuit samples logic states of signals it receives from the unit delay element outputs, synchronously with a rising edge of the delay line input clock signal; and
further, wherein, if all said logic state samples are logic-O, the delay detector circuit produces an indication that the unit delay from the input to the output of each unit delay element should be increased, and otherwise, produces an indication that the unit delay from the input to the output of each unit delay element should be decreased.
